(19) United States
(12) Patent Application Publication
(10) Pub. No.: US 2022/0334383 A1
(43) Pub. Date: Oct. 20, 2022

(54) CLEANING METHOD FOR EXTREME ULTRAVIOLET LIGHT REFLECTION MIRROR

(71) Applicant: Gigaphoton Inc., Tochigi (JP)

(72) Inventor: Gouta NIIMI, Oyama-shi (JP)

(73) Assignee: Gigaphoton Inc., Tochigi (JP)

(21) Appl. No.: 17/654,701

(22) Filed: Mar. 14, 2022

(30) Foreign Application Priority Data
Apr. 20, 2021 (JP) 2021-071040

(51) Int. Cl. G02B 27/00; B08B 7/00; B08B 5/02; G03F 7/20; C23C 14/34; C23C 14/18; C23C 14/28; B24C 1/00

(52) U.S. Cl. CPC G02B 27/0006; B08B 7/0014; B08B 5/02; G03F 7/70925; C23C 14/34; C23C 14/18; C23C 14/28; B24C 1/003; G03F 7/70033

(57) ABSTRACT

A cleaning method for an extreme ultraviolet light reflection mirror includes a contacting step of bringing α-tin into contact with solid tin debris attached to an extreme ultraviolet light reflection mirror and an aging step of leaving the tin debris brought into contact with the α-tin in a temperature environment below a freezing point to promote turning into tin pest of the tin debris. The cleaning method further includes a removing step of removing the tin debris turned into tin pest from the extreme ultraviolet light reflection mirror.

### CROSS-REFERENCE TO RELATED APPLICATIONS

The present application claims the benefit of Japanese Patent Application No. 2021-071040, filed on Apr. 20, 2021, the entire contents of which are hereby incorporated by reference.

### BACKGROUND

### 1. Technical Field

The present disclosure relates to a cleaning method for an extreme ultraviolet light reflection mirror.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: U.S. Pat. No. 7,211,810
Patent Document 2: Japanese Patent Publication No. 2005-268358

### SUMMARY

A cleaning method for an extreme ultraviolet light reflection mirror according to an aspect of the present disclosure includes a contacting step of bringing α-tin into contact with solid tin debris attached to an extreme ultraviolet light reflection mirror, an aging step of leaving the tin debris brought into contact with the α-tin in a temperature environment below a freezing point to promote turning into tin pest of the tin debris, and a removing step of removing the tin debris turned into tin pest from the extreme ultraviolet light reflection mirror.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire electronic device manufacturing apparatus different from the electronic device manufacturing apparatus shown in FIG. 1.

FIG. 3 is a schematic view showing a schematic configuration example of an entire extreme ultraviolet light generation apparatus.

FIG. 4 is a sectional view of an EUV light reflection mirror to which tin debris is attached.

FIG. 5 is an enlarged sectional view of the EUV light reflection mirror around the tin debris shown in FIG. 4.

FIG. 6 is a diagram showing an example of a flowchart of a cleaning method for the EUV light reflection mirror in the comparative example.

FIG. 7 is an enlarged sectional view of the EUV light reflection mirror having the tin debris and a reflection film removed.

FIG. 8 is an enlarged sectional view of the EUV light reflection mirror having the reflection film re-deposited.

FIG. 9 is a diagram showing an example of a flowchart of the cleaning method for the EUV light reflection mirror in a first embodiment.

FIG. 10 is a sectional view of the EUV light reflection mirror in a contacting step.

FIG. 11 is an enlarged sectional view of the EUV light reflection mirror around the tin debris shown in FIG. 10.

FIG. 12 is an enlarged sectional view of the EUV light reflection mirror around the tin debris in an aging step.

FIG. 13 is a view showing the state in a removing step.

FIG. 14 is a sectional view of the EUV light reflection mirror after the removing step.

FIG. 15 is a diagram showing an example of a flowchart of the cleaning method of a second embodiment.

FIG. 16 is a view showing the state in a depositing step.

FIG. 17 is an enlarged sectional view of the EUV light reflection mirror around the tin debris shown in FIG. 16.

FIG. 18 is an enlarged sectional view of the EUV light reflection mirror around the tin debris in the contacting step in the second embodiment.

FIG. 19 is an enlarged sectional view of the EUV light reflection mirror around the tin debris in the contacting step in a third embodiment.

### DESCRIPTION OF EMBODIMENTS

### 1. Overview

2. Description of electronic device manufacturing apparatus
3. Description of extreme ultraviolet light generation apparatus of comparative example

3.1 Configuration

3.2 Operation

3.3 Cleaning method for extreme ultraviolet light reflection mirror

3.4 Problem

4. Description of cleaning method for extreme ultraviolet light reflection mirror in first embodiment

4.1 Cleaning method for extreme ultraviolet light reflection mirror

4.2 Effects

5. Description of cleaning method for extreme ultraviolet light reflection mirror in second embodiment

5.1 Cleaning method for extreme ultraviolet light reflection mirror

5.2 Effects

6. Description of cleaning method for extreme ultraviolet light reflection mirror in third embodiment

6.1 Cleaning method for extreme ultraviolet light reflection mirror

6.2 Effects

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Overview

Embodiments of the present disclosure relate to an extreme ultraviolet light generation apparatus generating light having a wavelength of extreme ultraviolet (EUV) and an electronic device manufacturing apparatus. In the following, extreme ultraviolet light is referred to as EUV light in some cases.

### 2. Description of Electronic Device Manufacturing Apparatus

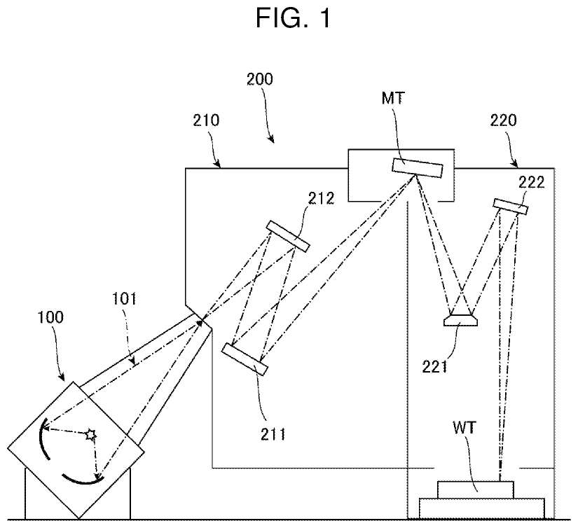

FIG. 1 is a schematic view showing a schematic configuration example of an entire electronic device manufacturing apparatus. The electronic device manufacturing apparatus shown in FIG. 1 includes an EUV light generation apparatus 100 and an exposure apparatus 200. The exposure apparatus 200 includes a mask irradiation unit 210 including a plurality of mirrors 211, 212 that constitute a reflection optical system, and a workpiece irradiation unit 220 including a plurality of mirrors 221, 222 that constitute a reflection optical system different from the reflection optical system of the mask irradiation unit 210. The mask irradiation unit 210 illuminates, via the mirrors 211, 212, a mask pattern of the mask table MT with EUV light 101 incident from the EUV light generation apparatus 100. The workpiece irradiation unit 220 images the EUV light 101 reflected by the mask table MT onto a workpiece (not shown) placed on the workpiece table WT via the mirrors 211, 212. The workpiece is a photosensitive substrate such as a semiconductor wafer on which photoresist is applied. The exposure apparatus 200 synchronously translates the mask table MT and the workpiece table WT to expose the workpiece to the EUV light 101 reflecting the mask pattern. Through the exposure steps as described above, a device pattern is transferred onto the semiconductor wafer, thereby a semiconductor device can be manufactured.

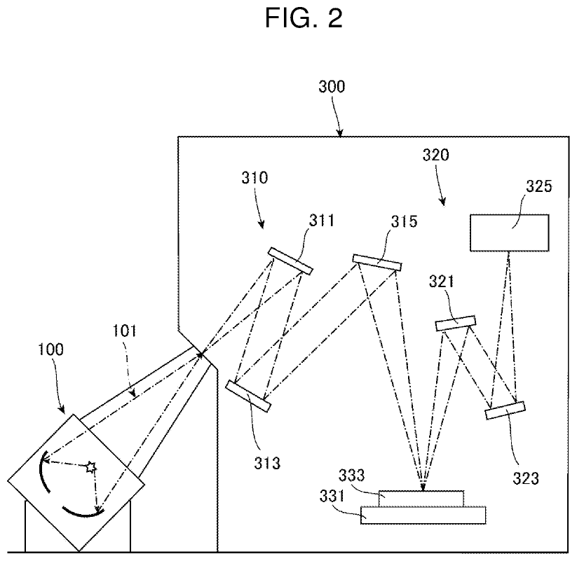

FIG. 2 is a schematic view showing a schematic configuration example of an entire electronic device manufacturing apparatus different from the electronic device manufacturing apparatus shown in FIG. 1. The electronic device manufacturing apparatus shown in FIG. 2 includes the EUV light generation apparatus 100 and an inspection apparatus 300. The inspection apparatus 300 includes an illumination optical system 310 including a plurality of mirrors 311, 313, 315 that constitute a reflection optical system, and a detection optical system 320 including a plurality of mirrors 321, 322 that constitute a reflection optical system different from the reflection optical system of the illumination optical system 310 and a detector 325. The illumination optical system 310 reflects, with the mirrors 311, 313, 315, the EUV light 101 incident from the EUV light generation apparatus 100 to illuminate a mask 333 placed on a mask stage 331. The mask 333 includes a mask blanks before a pattern is formed. The detection optical system 320 reflects, with the mirrors 321, 323, the EUV light 101 reflecting the pattern from the mask 333 and forms an image on a light receiving surface of the detector 325. The detector 325 having received the EUV light 101 obtains an image of the mask 333. The detector 325 is, for example, a time delay integration (TDI) camera. A defect of the mask 333 is inspected based on the image of the mask 333 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 200.

### 3. Description of Extreme Ultraviolet Light Generation Apparatus of Comparative Example

### 3.1 Configuration

The EUV light generation apparatus 100 of the comparative example will be described below. The comparative example of the present disclosure is an example recognized by the applicant as known only by the applicant, and is not a publicly known example admitted by the applicant. Further, the following description will be given with reference to the EUV light generation apparatus 100 that emits the EUV light 101 toward the exposure apparatus 200 as an external apparatus as shown in FIG. 1. Here, the EUV light generation apparatus 100 that emits the EUV light 101 to the inspection apparatus 300 as an external apparatus as shown in FIG. 2 can obtain the same operation and effect.

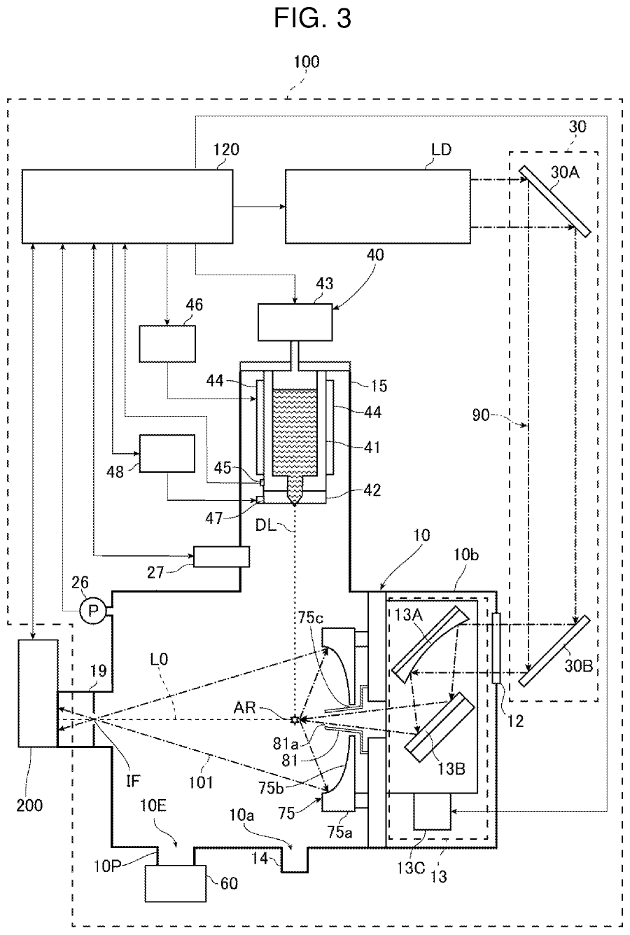

FIG. 3 is a schematic view showing a schematic configuration example of the entire EUV light generation apparatus 100 of the present example. As shown in FIG. 3, the EUV light generation apparatus 100 includes a laser device LD, a chamber device 10, a processor 120, and a laser light delivery optical system 30 as a main configuration.

The chamber device 10 is a sealable container. The chamber device 10 includes a sub-chamber 15 and a target supply device 40 is arranged in the sub-chamber 15. The target supply device 40 is attached to penetrate through a wall of the sub-chamber 15. The target supply device 40 includes a tank 41, a nozzle 42, and a pressure adjuster 43 to supply a droplet DL to the internal space of the chamber device 10. The droplet DL is also referred to as a target.

The tank 41 stores therein a target substance which becomes the droplet DL. The target substance contains tin. The inside of the tank 41 is in communication with the pressure adjuster 43 which regulates the pressure in the tank 41. A heater 44 and a temperature sensor 45 are attached to the tank 41. The heater 44 heats the tank 41 with current applied from a heater power source 46. Through the heating, the target substance in the tank 41 melts. The temperature sensor 45 measures, via the tank 41, the temperature of the target substance in the tank 41. The pressure adjuster 43, the temperature sensor 45, and the heater power source 46 are electrically connected to the processor 120.

The nozzle 42 is attached to the tank 41 and outputs the target substance. A piezoelectric element 47 is attached to the nozzle 42. The piezoelectric element 47 is electrically connected to a piezoelectric power source 48 and is driven by voltage applied from the piezoelectric power source 48. The piezoelectric power source 48 is electrically connected to the processor 120. The target substance output from the nozzle 42 is formed into the droplet DL through operation of the piezoelectric element 47.

The chamber device 10 includes a target collection unit 14. The target collection unit 14 is a box body attached to an inner wall 10b of the chamber device 10 and communicates with the internal space of the chamber device 10 via an opening 10a continued to the inner wall 10b of the chamber device 10. The opening 10a is arranged directly below the nozzle 42. The target collection unit 14 is a drain tank to collect any unnecessary droplet DL having passed through the opening 10a and reaching the target collection unit 14.

At least one through hole is formed in the inner wall 10b of the chamber device 10. The through hole is blocked by a window 12 through which pulse laser light 90 output from the laser device LD passes.

Further, a laser light concentrating optical system 13 is arranged at the internal space of the chamber device 10. The laser light concentrating optical system 13 includes a laser light concentrating mirror 13A and a high reflection mirror 13B. The laser light concentrating mirror 13A reflects and concentrates the laser light 90 having passed through the window 12. The high reflection mirror 13B reflects light concentrated by the laser light concentrating mirror 13A. Positions of the laser light concentrating mirror 13A and the high reflection mirror 13B are adjusted by a laser light manipulator 13C so that a concentrating position of the laser light 90 at the internal space of the chamber device 10 coincides with a position specified by the processor 120. The concentrating position is adjusted to be positioned directly below the nozzle 42, and when the target substance constituting the droplet DL is irradiated with the laser light 90 at the concentrating position, plasma is generated by the irradiation, and the EUV light 101 is radiated from the plasma. In the following, the region in which plasma is generated is sometimes referred to as a plasma generation region AR.

An EUV light reflection mirror 75 is arranged at the internal space of the chamber device 10. The EUV light reflection mirror 75 has a first focal point and a second focal point. The EUV light reflection mirror 75 is arranged such that, for example, the first focal point is located in the plasma generation region AR and the second focal point is located at an intermediate focal point IF. In FIG. 3, a straight line passing through the first focal point and the second focal point is shown as a focal line L0. The focal line L0 is located along the center axis direction of the EUV light reflection mirror 75. The EUV light reflection mirror 75 includes a spheroidal substrate 75a and a reflection film 75b arranged on the surface of the substrate 75a on the plasma generation region AR side. The reflection film 75b reflects the EUV light 101 radiated from the plasma in the plasma generation region AR, and the EUV light reflection mirror 75 concentrates the EUV light 101 to the second focal point owing to the shape thereof. In FIG. 3, the reflection film 75b is simply shown to avoid complication of the drawing.

The reflection film 75b includes a reflective main body film laminated on the substrate 75a and a protective film laminated on the reflective main body film. The reflective main body film is a laminated film in which silicon layers and molybdenum layers are alternately laminated. The number of layers of the reflective main body film is preferably, for example, equal to or more than 50 and equal to or less than 100. For the EUV light 101 having a wavelength of 13.5 nm, the actual refractive index of the silicon layers is approximately 0.99, and the actual refractive index of the molybdenum layers is approximately 0.92. The outermost layer of the reflective main body film is the silicon layer, and the protective film is laminated on the silicon layer. The protective film is made of any one of zirconium oxynitride (ZrON), zirconium nitride (ZrN), zirconia (ZrO₂), titanium nitride (TiN), titanium oxynitride (TiON), titanium dioxide (TiO₂), ruthenium dioxide (RuO₂), silicon nitride (Si₃N₄), silicon dioxide (SiO₂), and molybdenum dioxide (MoO₂). One surface of the protective film is the outermost layer of the reflection film 75b and is exposed to the internal space of the chamber device 10. Here, a film other than the silicon layer and molybdenum layer may be used for the reflective main body film, and for example, a single layer film of ruthenium may be provided.

The EUV light generation apparatus 100 includes a connection portion 19 providing communication between the internal space of the chamber device 10 and an internal space of the exposure apparatus 200. A wall in which an aperture is formed is arranged inside the connection portion 19. The wall is preferably arranged such that the aperture is located at the second focal point. The connection portion 19 is an output port of the EUV light 101 in the EUV light generation apparatus 100, and the EUV light 101 is output from the connection portion 19 and enters the exposure apparatus 200.

Further, the EUV light generation apparatus 100 includes a pressure sensor 26 and a target sensor 27. The pressure sensor 26 and the target sensor 27 are attached to the chamber device 10 and are electrically connected to the processor 120. The pressure sensor 26 measures the pressure at the internal space of the chamber device 10 and outputs a signal indicating the measured pressure to the processor 120. The target sensor 27 has, for example, an imaging function, and detects the presence, trajectory, position, velocity, and the like of the droplet DL output from the nozzle hole of the nozzle 42 in accordance with an instruction from the processor 120. The target sensor 27 may be arranged inside the chamber device 10, or may be arranged outside the chamber device 10 and detect the droplet DL through a window (not shown) arranged on a wall of the chamber device 10. The target sensor 27 includes a light receiving optical system (not shown) and an imaging unit (not shown) such as a charge-coupled device (CCD) or a photodiode. In order to detect the droplet DL, the light receiving optical system forms an image of the trajectory of the droplet DL and the periphery thereof on a light receiving surface of the imaging unit. When the droplet DL passes through a concentrating region of a light source unit (not shown) of the target sensor 27 arranged to secure the field of view of the target sensor 27, the imaging unit detects a change of the light passing through the trajectory of the droplet DL and the periphery thereof. The imaging unit converts the detected light change into an electric signal as a signal related to the image data of the droplet DL. The imaging unit outputs the electric signal to the processor 120.

The laser device LD includes a master oscillator being a light source to perform burst operation. The master oscillator outputs the pulse laser light 90 in a burst-on duration. The master oscillator is, for example, a laser device configured to output the laser light 90 by exciting, through electric discharge, gas as mixture of carbon dioxide gas with helium, nitrogen, or the like. Alternatively, the master oscillator may be a quantum cascade laser device. The master oscillator may output the pulse laser light 90 by a Q switch system. Further, the master oscillator may include an optical switch, a polarizer, and the like. In the burst operation, the pulse laser light 90 is continuously output at a predetermined repetition frequency in the burst-on duration and the output of the laser light 90 is stopped in a burst-off duration.

A travel direction of the laser light 90 output from the laser device LD is adjusted by the laser light delivery optical system 30. The laser light delivery optical system 30 includes a plurality of mirrors 30A, 30B for adjusting the travel direction of the laser light 90. The position of at least one of the mirrors 30A, 30B is adjusted by an actuator (not shown). Owing to that the position of at least one of the mirrors 30A, 30B is adjusted, the laser light 90 can appropriately propagate to the internal space of the chamber device 10 through the window 12.

The processor 120 of the present disclosure is a processing device including a storage device in which a control program is stored and a CPU which executes the control program. The processor 120 is specifically configured or programmed to perform various processes included in the present disclosure. The processor 120 controls the entire EUV light generation apparatus 100. Further, the processor 120 is electrically connected to the exposure apparatus 200 and transmits and receives various signals to and from the exposure apparatus 200.

A central gas supply unit 81 for supplying etching gas to the internal space of the chamber device 10 is arranged at the chamber device 10. As described above, since the target substance contains tin, the etching gas is, for example, hydrogen-containing gas having a hydrogen gas concentration of 100% in effect. Alternatively, the etching gas may be, for example, a balance gas having a hydrogen gas concentration of approximately 3%. The balance gas contains nitrogen (N₂) gas and argon (Ar) gas. Tin fine particles and tin charged particles are generated when the target substance constituting the droplet DL is turned into plasma in the plasma generation region AR by being irradiated with the laser light 90. Tin constituting these fine particles and charged particles reacts with hydrogen contained in the etching gas supplied to the internal space of the chamber device 10. Through the reaction with hydrogen, tin becomes stannane (SnH₄) gas at room temperature.

The central gas supply unit 81 has a shape of a side surface of a circular truncated cone and is called a cone in some cases. The central gas supply unit 81 is inserted through a through hole 75c formed in the center of the EUV light reflection mirror 75.

The central gas supply unit 81 has a central gas supply port 81a being a nozzle. The central gas supply port 81a is arranged on the focal line L0. The central gas supply port 81a supplies the etching gas from the center side of the EUV light reflection mirror 75 toward the plasma generation region AR. The central gas supply port 81a preferably supplies the etching gas in the direction away from the EUV light reflection mirror 75 from the center side of the EUV light reflection mirror 75 along the focal line L0. The central gas supply port 81a is connected to a gas supply device (not shown) being a tank through a pipe (not shown) of the central gas supply unit 81 and the etching gas is supplied therefrom. The gas supply device is driven and controlled by the processor 120. A supply gas flow rate adjusting unit being a valve (not shown) may be arranged in the pipe (not shown).

The central gas supply port 81a is a gas supply port for supplying the etching gas to the internal space of the chamber device 10 as well as an emission port through which the laser light 90 is output to the internal space of the chamber device 10. The laser light 90 travels toward the internal space of the chamber device 10 through the window 12 and the central gas supply port 81a.

An exhaust port 10E is continued to the inner wall 10b of the chamber device 10. Since the exposure apparatus 200 is arranged on the focal line L0, the exhaust port 10E is arranged not on the focal line L0 but on the inner wall 10b on the side lateral to the focal line L0. The direction along the center axis of the exhaust port 10E is perpendicular to the focal line L0. The exhaust port 10E is arranged on the side opposite to the reflection film 75b with respect to the plasma generation region AR when viewed from the direction perpendicular to the focal line L0. The exhaust port 10E exhausts residual gas to be described later at the internal space of the chamber device 10. The exhaust port 10E is connected to an exhaust pipe 10P, and the exhaust pipe 10P is connected to an exhaust pump 60.

As described above, when the target substance is turned into plasma in the plasma generation region AR, the residual gas as exhaust gas is generated at the internal space of the chamber device 10. Residual gas contains fine particles and charged particles of tin generated through the plasma generation from the target substance, stannane generated through the reaction of the fine particles and charged particles of tin with the etching gas, and unreacted etching gas. Some of the charged particles are neutralized at the internal space of the chamber device 10, and the residual gas contains the neutralized charged particles as well. The residual gas is sucked to the exhaust pump 60 through the exhaust port 10E and the exhaust pipe 10P.

### 3.2 Operation

Next, operation of the EUV light generation apparatus 100 of the comparative example will be described. In the EUV light generation apparatus 100, for example, at the time of new installation or maintenance or the like, atmospheric air at the internal space of the chamber device 10 is exhausted. At this time, purging and exhausting of the internal space of the chamber device 10 may be repeated for exhausting atmospheric components. For example, inert gas such as nitrogen or argon is preferably used for the purge gas. Thereafter, when the pressure at the internal space of the chamber device 10 becomes equal to or lower than a predetermined pressure, the processor 120 starts introduction of the etching gas from the gas supply device to the internal space of the chamber device 10 through the central gas supply unit 81. At this time, the processor 120 may control the supply gas flow rate adjusting unit (not shown) and the exhaust pump 60 so that the pressure at the internal space of the chamber device 10 is maintained at the predetermined pressure. Thereafter, the processor 120 waits until a predetermined time elapses from the start of introduction of the etching gas.

Further, the processor 120 causes the gas at the internal space of the chamber device 10 to be exhausted from the exhaust port 10E by the exhaust pump 60, and keeps the pressure at the internal space of the chamber device 10 substantially constant based on the signal of the pressure at the internal space of the chamber device 10 measured by the pressure sensor 26.

In order to heat and maintain the target substance in the tank 41 at a predetermined temperature equal to or higher than the melting point, the processor 120 causes the heater power source 46 to apply current to the heater 44 to increase temperature of the heater 44. In this case, the processor 120 controls the temperature of the target substance to the predetermined temperature by adjusting a value of the current applied from the heater power source 46 to the heater 44 based on an output from the temperature sensor 45. When the target substance is tin, the predetermined temperature is equal to or higher than 231.93° C. being the melting point of tin and, for example, is equal to or higher than 240° C. and equal to or lower than 290° C.

Further, the processor 120 causes the pressure adjuster 43 to supply the inert gas from the gas supply source to the tank 41 and to adjust the pressure in the tank 41 so that the melted target substance is output through the nozzle hole of the nozzle 42 at a predetermined velocity. Under this pressure, the target substance is output through the nozzle hole of the nozzle 42. The target substance output through the nozzle hole may be in the form of a jet. At this time, the processor 120 causes the piezoelectric power source 48 to apply voltage having a predetermined waveform to the piezoelectric element 47 to generate the droplet DL. The piezoelectric power source 48 applies voltage so that the waveform of the voltage value becomes, for example, a sine wave, a rectangular wave, or a sawtooth wave. Vibration of the piezoelectric element 47 can propagate through the nozzle 42 to the target substance to be output through the nozzle hole of the nozzle 42. The target substance is divided at a predetermined cycle by the vibration into liquid droplets DL.

The target sensor 27 detects passage timing of the droplet DL passing through a predetermined position at the internal space of the chamber device 10. The processor 120 outputs, to the laser device LD, a light emission trigger signal synchronized with a signal from the target sensor 27. When the light emission trigger signal is input, the laser device LD outputs the pulse laser light 90. The output laser light 90 is incident on the laser light concentrating optical system 13 through the laser light delivery optical system 30 and the window 12. Further, the laser light 90 travels from the laser light concentrating optical system 13 to the central gas supply unit 81 which is an emission portion. The laser light 90 is output along the focal line L0 toward the plasma generation region AR from the central gas supply port 81a, which is the emission port of the central gas supply unit 81, and is radiated to the droplet DL in the plasma generation region AR. At this time, the processor 120 controls the laser light manipulator 13C of the laser light concentrating optical system 13 so that the laser light 90 is concentrated in the plasma generation region AR. The processor 120 controls the timing of outputting the laser light 90 from the laser device LD based on the signal from the target sensor 27 so that the droplet DL is irradiated with the laser light 90. Thus, the droplet DL is irradiated in the plasma generation region AR with the laser light 90 concentrated by the laser light concentrating mirror 13A. Plasma is generated by the irradiation, and light including EUV light is radiated from the plasma.

Among the light including the EUV light generated in the plasma generation region AR, the EUV light 101 is concentrated at the intermediate focal point IF by the EUV light reflection mirror 75, and then is incident on the exposure apparatus 200 from the connection portion 19.

When the target substance is turned into plasma, tin fine particles are generated as described above. The fine particles diffuse to the internal space of the chamber device 10. The fine particles diffusing to the internal space of the chamber device 10 react with the hydrogen-containing etching gas supplied from the central gas supply unit 81 to become stannane. Most of the stannane obtained through the reaction with the etching gas flows into the exhaust port 10E along with the flow of the unreacted etching gas. At least some of the unreacted charged particles, fine particles, and etching gas flow into the exhaust port 10E.

The unreacted etching gas, fine particles, charged particles, stannane, and the like having flowed into the exhaust port 10E flow as residual gas through the exhaust pipe 10p into the exhaust pump 60 and are subjected to predetermined exhaust treatment such as detoxification.

### 3.3 Cleaning Method for Extreme Ultraviolet Light Reflection Mirror

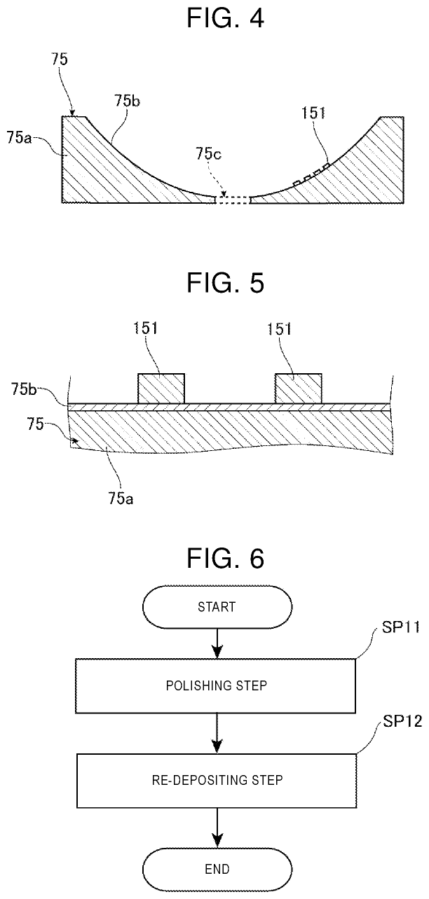

Tin generated when the target material is turned into plasma and diffused to the internal space of the chamber device 10 may be attached to the reflection film 75b as tin debris 151. FIG. 4 is a sectional view of the EUV light reflection mirror 75 to which the tin debris 151 is attached. FIG. 5 is an enlarged sectional view of the EUV light reflection mirror 75 around the tin debris 151 shown in FIG. 4. In FIG. 4, for ease of viewing, only one piece of tin debris 151 is denoted by a reference numeral, and the reference numerals of the other pieces of tin debris 151 are omitted. In FIG. 4, in order to avoid complication of the drawing, the reflection film 75b is simply shown, and hatching of the tin debris 151 is omitted. In FIG. 5, two pieces of tin debris 151 among the tin debris 151 shown in FIG. 4 are shown in an enlarged manner. As shown in FIGS. 4 and 5, the tin debris 151 tends to be attached to the reflection film 75b as being scattered. Therefore, each piece of tin debris 151 is attached to the reflection film 75b separated from each other. Although FIG. 4 shows an example in which the tin debris 151 is scattered in a part of the reflection film 75b, the tin debris 151 may be scattered over the entire reflection film 75b in some cases. The tin debris 151 may be adhered to the reflection film 75b in some cases.

The tin debris 151 is a solid tin containing at least β-tin. β-tin is metallic tin that tends to exist at temperature higher than approximately 13.2° C. and is harder than α-tin. α-tin is an allotrope of tin that tends to exist at temperature equal to or lower than approximately 13.2° C. and is more brittle than β-tin. α-tin is a gray cubic crystal and β-tin is a white tetragonal crystal. When the tin debris 151 is attached to the reflection film 75b, reflectance of the reflection film 75b is reduced and the energy of the EUV light 101 output from the EUV light generation apparatus 100 to the exposure apparatus 200 is reduced. Therefore, in the EUV light generation apparatus 100 of the comparative example, cleaning of the EUV light reflection mirror 75 is performed in order to maintain high reflectance.

FIG. 6 is a diagram showing an example of a flowchart of a cleaning method for the EUV light reflection mirror 75 in the comparative example. In the following, the cleaning method for the EUV light reflection mirror 75 may be simply referred to as a cleaning method. As shown in FIG. 6, the cleaning method includes a polishing step SP11 and a re-depositing step SP12. In the state at start shown in FIG. 6, the tin debris 151 is attached to the reflection film 75b as shown in FIGS. 4 and 5.

### (Polishing Step SP11)

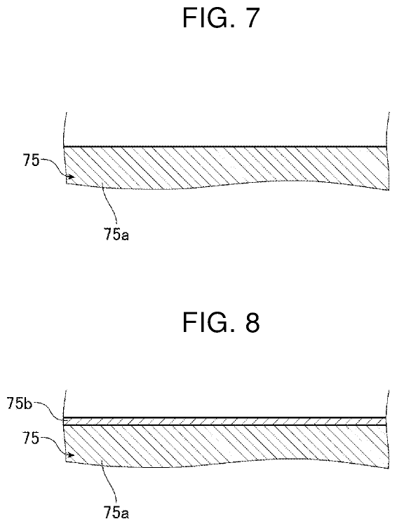

In the present step, the entire reflection film 75b is polished, and the reflection film 75b is removed together with the tin debris 151 as shown in FIG. 7. Therefore, in the present step, the entire surface of the substrate 75a is exposed. When the reflection film 75b is removed, the flow proceeds to the re-depositing step SP12.

### (Re-Depositing Step SP12)

In the present step, as shown in FIG. 8, a new reflection film 75b having no tin debris 151 attached thereto is re-deposited on the entire surface of the substrate 75a. As a result, the reflectance of the reflection film 75b recovers as returning to the reflectance before the tin debris 151 is attached to the reflection film 75b. When the reflection film 75b is re-deposited, the flow ends.

### 3.4 Problem

Cleaning the EUV light reflection mirror 75 in the comparative example in which removing of the entire reflection film 75b and re-deposition of the reflection film 75b on the entire surface of the substrate 75a are performed takes time and cost. Accordingly, it is required to shorten the cleaning period and reduce the cleaning cost.

Therefore, in the following embodiments, a cleaning method for the EUV light reflection mirror 75 capable of shortening the cleaning period and reducing the cleaning cost is exemplified.

### 4. Description of Cleaning Method for Extreme Ultraviolet Light Reflection Mirror in First Embodiment

Next, the cleaning method of a first embodiment will be described. Any component same as that described above is denoted by an identical reference sign, and duplicate description thereof is omitted unless specific description is needed.

### 4.1 Cleaning Method for Extreme Ultraviolet Light Reflection Mirror

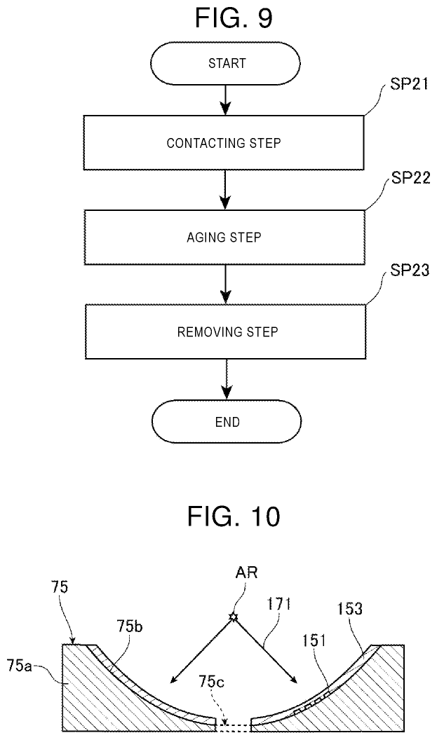

FIG. 9 is a diagram showing an example of a flowchart of the cleaning method of the present embodiment. The cleaning method of the present embodiment includes a contacting step SP21, an aging step SP22, and a removing step SP23. The state at start shown in FIG. 9 is the same as that of the cleaning method of the comparative example. Therefore, in the state at start, the tin debris 151 is attached to the reflection film 75b as being scattered as shown in FIGS. 4 and 5.

### (Contacting Step SP21)

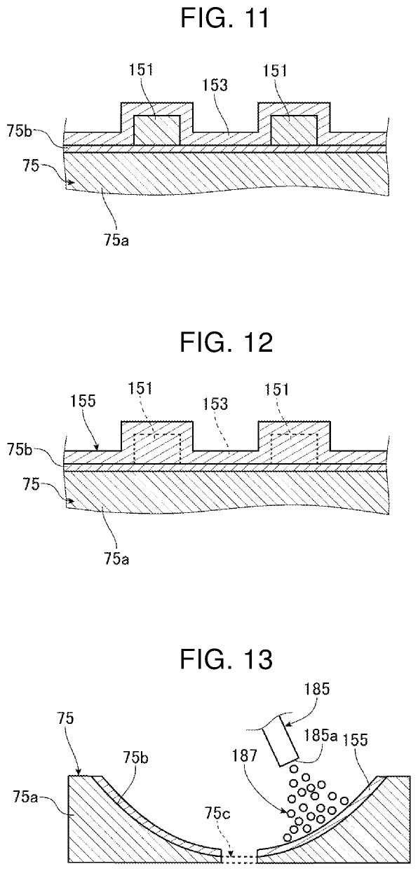

FIG. 10 is a sectional view of the EUV light reflection mirror 75 in the present step. FIG. 11 is an enlarged sectional view of the EUV light reflection mirror 75 around the tin debris 151 shown in FIG. 10. In FIG. 10, for ease of viewing, only one piece of tin debris 151 is denoted by a reference numeral, and the reference numerals of the other pieces of tin debris 151 are omitted. In FIG. 10, in order to avoid complication of the drawing, the reflection film 75b and an α-tin film described later are simply shown, and hatching of the tin debris 151 is omitted. In FIG. 11, two pieces of tin debris 151 among the tin debris 151 shown in FIG. 10 are shown in an enlarged manner. In FIG. 10, the plasma emitted from the plasma generation region AR is indicated by arrows 171. The tin plasma indicated by the arrows 171 is generated in an environment containing hydrogen by a processing device (not shown) described later.

The present step is a step of bringing α-tin into contact with the solid tin debris 151 attached to the EUV light reflection mirror 75. FIGS. 10 and 11 show an example in which an α-tin film 153 containing α-tin is deposited on the tin debris 151 by exposure of tin ions and tin neutral atoms released from plasma. In the present step, since tin ions and tin neutral atoms are also exposed to the reflection film 75b, the α-tin film 153 is also deposited on the reflection film 75b. The thickness of the α-tin film 153 is approximately equal to or larger than 20 μm and equal to or smaller than 1 mm. Although the thickness of the α-tin film 153 is substantially the same at any position, the α-tin film 153 deposited on the tin debris 151 may be thicker or thinner than the α-tin film 153 deposited on the reflection film 75b.

The processing device deposits the α-tin film 153 on the tin debris 151 with tin ions and tin neutral atoms released from the plasma generated by irradiating the liquid droplet tin or solid tin with laser light. Here, the processing device may deposit the α-tin film 153 on the tin debris 151 with tin ions and tin neutral atoms released from the plasma generated from stannane. In the processing device described above, the energy of each tin ions and tin neutral atoms released from the plasma is smaller than 0.5 eV. Alternatively, the processing device may deposit the α-tin film 153 by sputtering.

In the present step, the tin plasma is generated in an environment containing hydrogen. The temperature of the EUV light reflection mirror 75 is adjusted so as to be approximately equal to or lower than 13.2° C., which is the phase transition temperature of α-tin. As a result, the temperature of each of the tin debris 151 and the reflection film 75b is also adjusted to approximately equal to or lower than 13.2° C. In this case, by exposing tin ions and tin neutral atoms to the tin debris 151, seed crystals of α-tin are generated on the surface of the tin debris 151. The pressure in the environment containing hydrogen is approximately equal to or higher than 0.1 Pa and equal to or lower than 1000 Pa.

It is preferable that the purity of tin used in the processing device is approximately equal to or higher than 99.999%. The higher the purity of tin is, the more the turning into tin pest described later is promoted.

When the α-tin film 153 is directly deposited on the tin debris 151 and the reflection film 75b, the flow proceeds to the aging step SP22. At this time, a part of the tin debris 151 may be turned into tin pest.

### (Aging Step SP22)

In the present step, the tin debris 151 on which the α-tin film 153 containing α-tin is deposited is left in a temperature environment below the freezing point to promote turning into tin pest of the tin debris 151. Turning into tin pest is a phenomenon in which a seed crystal of α-tin comes into contact with β-tin, thereby β-tin undergoes phase transition to α-tin from a contact portion between the seed crystal and β-tin as a starting point. Since α-tin tends to exist at approximately 13.2° C. or lower, phase transition of β-tin to α-tin is initiated at approximately 13.2° C. or lower in turning into tin pest. Therefore, in the contacting step SP21, when the α-tin film 153 is deposited on the tin debris 151 containing β-tin, the phase transition is initiated and the tin debris 151 is turned into tin pest. Since turning into tin pest is promoted under the temperature environment below the freezing point as in the present step, the storage period described below under the temperature environment below the freezing point is shorter than the storage period under the environment in which turning into tin pest is less likely to be promoted. The temperature of the environment is approximately higher than 0° C. and equal to or lower than 13.2° C.

In the present step, in order to promote turning into tin pest, the α-tin film 153, the tin debris 151, and the EUV light reflection mirror 75 are stored in an internal space of a storage device (not shown) at the temperature environment below the freezing point. In the tin debris 151 in which turning into tin pest is promoted, the ratio of α-tin in the tin debris 151 increases over time. FIG. 12 is an enlarged sectional view of the EUV light reflection mirror 75 around tin debris 155 in the aging step S22. In FIG. 12, for comparison with the enlarged sectional view shown in FIG. 11, the tin debris 151 and the α-tin film 153 shown in FIG. 11 are shown as broken lines. The tin debris 155 is formed of the α-tin film 153 and the tin debris 151 which has been turned into tin pest by the α-tin film 153. The period required for turning into tin pest, that is, the storage period of the tin debris 151 at the internal space of the storage device varies in accordance with the temperature at the internal space. Under the temperature environment below the freezing point, the storage period is shorter than that under the environment in which turning into tin pest is less likely to be promoted. When the temperature is approximately equal to or higher than −50° C. and equal to or lower than −20° C. in the temperature environment below the freezing point, the storage period is further shortened. When the temperature is approximately −40° C., the speed of the phase transition is the fastest and the storage period is the shortest.

In turning into tin pest of the present step, as the ratio of α-tin in the tin debris 151 increases, the volume of the tin debris 151 gradually increases, the intensity of the tin debris 151 gradually decreases, and the color of the tin debris 151 gradually changes. When turning into tin pest is completed, the volume of the tin debris 155 increases by approximately 30% compared with before turning into tin pest, and the tin debris 155 turns gray. Note that the volume before turning into tin pest is the sum of the respective volumes of the tin debris 151 and the α-tin film 153 before turning into tin pest. Also, since most part of the tin debris 155 becomes sand granular, the tin debris 155 is brittle compared with the tin debris 151, and is removed in the removing step SP23. Note that, if the tin debris 155 is removed in the removing step SP23, the ratio of α-tin in the tin debris 151, 155 does not need to be 100%. In the present step, the tin debris 151 is left in the temperature environment below the freezing point so that the tin debris 155 is removed in the removing step SP23, and when the ratio of α-tin in the tin debris 151 becomes equal to or larger than a predetermined value, the tin debris 151 can be regarded as having been turned into tin pest. In FIG. 12, the increase in volume and the sand grains are not shown in order to avoid complication of the drawing.

The proportion of moisture in the environment in which the present step is performed is equal to or lower than 0.1 wt %. Such an environment is a dry environment in which moisture does not condense on the tin debris 151, 155, the α-tin film 153, and the reflection film 75b.

When the tin debris 155 has been generated, the flow proceeds to the removing step SP23.

### (Removing Step SP23)

FIG. 13 is a view showing the state in the present step. In the present step, the tin debris 155 turned into tin pest is removed from the EUV light reflection mirror 75. In the present step, the EUV light reflection mirror 75 is taken out from the storage device and the tin debris 155 is removed from the EUV light reflection mirror 75 by a jet. Examples of the removing method using a jet include a dry ice jet method in which dry ice 187 is sprayed toward the tin debris 155, and a gas jet method in which gas is sprayed toward the tin debris 155.

Examples of the dry ice jet method include a first dry ice jet method in which pellet-like dry ice 187 is sprayed toward the tin debris 155, and a second dry ice jet method in which snow-like dry ice 187 is sprayed toward the tin debris 155. FIG. 13 shows an example in which a cleaning device 185 sprays the dry ice 187 to a part of the tin debris 155 with the first dry ice jet method. Here, the dry ice 187 is sprayed to the entire tin debris 155. Although the shape of the dry ice 187 is shown as a circle in FIG. 13, the shape is not particularly limited.

In the first dry ice jet method, the cleaning device 185 sprays, from a nozzle hole 185a of the cleaning device 185, the pellet-like dry ice 187 generated from liquefied carbon dioxide gas toward the tin debris 155. The dry ice 187 is sprayed in a state of being mixed with compressed air. The pressure of the compressed air is approximately 0.5 MPa. In the first dry ice jet method, when the cleaning device 185 sprays the dry ice 187, most part of the tin debris 155 is peeled and scattered from the reflection film 75b by the spraying of the dry ice 187, and is removed from the reflection film 75b. The dry ice 187 collides at high speed with the remaining part of the tin debris 155 that is not removed by the spraying. The tin debris 155 with which the dry ice 187 collides is heat shrunk due to cooling by the dry ice 187 at approximately −79° C. Due to the collision and the heat shrinkage, cracks (not shown) are generated in the tin debris 155. The dry ice 187 sprayed from the nozzle hole 185a is successively fed into the cracks. When the dry ice 187 is vaporized and expanded in the cracks, the tin debris 155 is peeled and scattered from the reflection film 75b by the vaporization and expansion of the dry ice 187, and is removed from the reflection film 75b.

In the second dry ice jet method, the cleaning device 185 sprays, from a nozzle hole 185a of the cleaning device 185, the snow-like dry ice 187 generated from liquefied carbon dioxide gas toward the tin debris 155. The dry ice 187 is sprayed in a state of being mixed with compressed air in the same manner as in the first dry ice jet method. In this case, the tin debris 155 is removed in the same manner as in the first ice jet method. In the second ice jet method, the snow-like dry ice 187 enters into minute gaps between the tin debris 155 and the surface of the reflection film 75b. When the dry ice 187 is vaporized and expanded in the gaps, the tin debris 155 is peeled and scattered from the reflection film 75b by the vaporization and expansion of the dry ice 187, and is removed from the reflection film 75b.

In the dry ice jet method, the volume of the dry ice 187 expands approximately 400 times to 800 times as large as that before expansion. Further, since the dry ice 187 sublimes to gas, the dry ice 187 does not remain on the reflection film 75b.

In the gas jet method, the cleaning device 185 sprays gas such as air or nitrogen from the nozzle hole 185a of the cleaning device 185 toward the tin debris 155. The tin debris 155 is peeled and scattered from the reflection film 75b by the spraying and is removed from the reflection film 75b. The cleaning by the gas jet method may be performed after the cleaning by the dry ice jet method. As a result, the tin debris 155 remaining on the reflection film 75b without being removed from the reflection film 75b by the vaporization and expansion of the dry ice 187 is removed from the reflection film 75b by the spraying of gas. The cleaning by the gas jet method may be performed before the cleaning by the dry ice jet method.

The proportion of moisture in the environment in which the present step is performed is equal to or lower than 0.1 wt % as in the aging step SP22.

Here, in the present step, the tin debris 155 may be removed by a wet cleaning method. In this case, for example, a fluorine-based inert liquid is used.

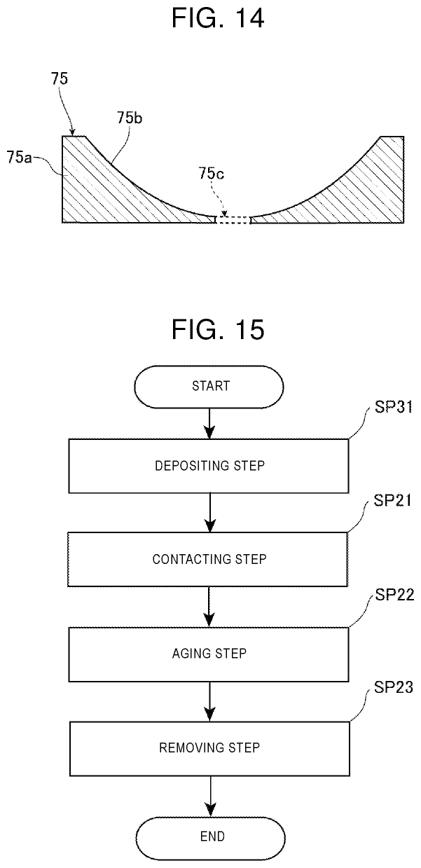

When the tin debris 155 is removed in the removing step SP23, the flow ends. FIG. 14 is a sectional view of the EUV light reflection mirror 75 after the removing step SP23. The enlarged sectional view of the EUV light reflection mirror 75 after the removing step SP23 is the same as the enlarged sectional view shown in FIG. 8. After the removing step SP23, the tin debris 155 is removed and the reflection film 75b is exposed. When the reflection film 75b is exposed, the reflectance of the reflection film 75b recovers as returning to the reflectance before the tin debris 151 is attached.

### 4.2 Effects

The cleaning method of the present embodiment includes the contacting step SP21 of bringing α-tin into contact with the solid tin debris 151 attached to the EUV light reflection mirror 75, the aging step SP22 of leaving the tin debris 151 in contact with α-tin in a temperature environment below the freezing point to promote turning into tin pest of the tin debris 151, and the removing step SP23 of removing the tin debris 155 turned into tin pest from the EUV light reflection mirror 75.

In the contacting step SP21, α-tin comes into contact with the solid tin debris 151, and in the aging step SP22, the tin debris 151 is left in the temperature environment below the freezing point, so that turning into tin pest of the tin debris 151 is promoted. As turning into tin pest is promoted, the tin debris 155 turned into tin pest becomes more brittle than the tin debris 151 before being turned into tin pest. The brittle tin debris 155 is removed from the EUV light reflection mirror 75 in the removing step SP23. Such a cleaning method can shorten the cleaning period and reduce the cleaning cost as compared with a case in which removing of the entire reflection film 75b is performed by polishing and re-depositing the reflection film 75b is performed on the entire surface of the substrate 75a. In the cleaning method of the present embodiment, it may be unnecessary to perform removing of the entire reflection film 75b by polishing and re-depositing on the entire surface of the substrate 75a. In the cleaning method of the present embodiment, the tin debris 151 is left in the temperature environment below the freezing point to promote turning into tin pest of the tin debris 151. As a result, the cleaning period can be shortened as compared with a case in which turning into tin pest is not promoted. In the cleaning method of the present embodiment, the tin debris 155 is made brittle by being turned into tin pest. As a result, the tin debris 155 can be easily removed as compared with a case in which the tin debris 155 does not become brittle.

Further, in the contacting step SP21 of the cleaning method of the present embodiment, the α-tin film 153 containing α-tin is deposited on the tin debris 151. In this case, as compared with a case in which α-tin is brought into point contact with the tin debris 151, the contact portion between α-tin and β-tin is widened, the turning into tin pest of the tin debris 151 in the aging step SP22 may be promoted, and the period of the aging step SP22 may be shortened.

Further, in the cleaning method of the present embodiment, the thickness of the α-tin film 153 is equal to or larger than 20 μm and equal to or smaller than 1 mm. The thicker the film thickness is, the more easily the α-tin film 153 can be deposited on the tin debris 151 without gaps, so that the tin debris 155 can be easily removed from the reflection film 75b in the removing step SP23. Here, the film thickness may be smaller than 20 μm or larger than 1 mm.

Further, in the cleaning method of the present embodiment, the α-tin film 153 is deposited on the tin debris 151 by tin ions and tin neutral atoms released from the tin plasma generated in the environment containing hydrogen. Thus, as compared with a case in which the tin film 153 is not deposited, seed crystals of α-tin can be easily generated on the surface of the tin debris 151. When seed crystals of α-tin are easily generated, the α-tin film 153 containing α-tin can be easily deposited.

Further, in the cleaning method of the present embodiment, the energy of each tin ions and tin neutral atoms released from the plasma is smaller than 0.5 eV. Tin ions and tin neutral atoms may collide with the protective film of the reflection film 75b to damage the protective film, or may enter the reflection film 75b to deteriorate the reflective main body film and cause a decrease in reflectance. When the energy is smaller than 0.5 eV as described above, damage to the protective film and deterioration of the reflective main body film can be suppressed as compared with a case in which the energy is equal to or larger than 0.5 eV. However, the energy in each case may be equal to or larger than 0.5 eV.

Further, in the aging step SP22 of the cleaning method of the present embodiment, the temperature of the temperature environment below the freezing point is approximately equal to or higher than −50° C. and equal to or lower than −20° C. Under the temperature environment below the freezing point, the cleaning period is shortened compared with an environment in which turning into tin pest is less likely to be promoted. Here, the temperature may be lower than −50° C. or higher than −20° C. as long as being below the freezing point.

Further, the proportion of moisture in the environment in which each of the aging step SP22 and the removing step SP23 of the cleaning method of the present embodiment is performed is equal to or lower than 0.1 wt %. As a result, adhesion of moisture to the reflection film 75b and oxidation of the reflection film 75b due to the adhesion can be suppressed. Further, an increase in the thickness of the reflection film 75b due to oxidization and a decrease in reflectance due to the increase can be suppressed. Here, the proportion in each step may be higher than 0.1 wt %.

Further, in the removing step SP23 of the cleaning method of the present embodiment, the tin debris 155 turned into tin pest is removed by a jet. If the tin debris 155 is removed by polishing, there may be a case that the reflection film 75b is polished and the reflection film 75b is damaged by polishing. When the tin debris 155 is removed by a jet, damage to the reflection film 75b can be suppressed and the time taken to remove the tin debris 155 can be shortened compared with a case in which the tin debris 155 is removed by polishing. Further, in the first dry ice jet method in which the pellet-like dry ice 187 is sprayed, the dry ice 187 is large compared with that in the second dry ice jet system in which the snow-like dry ice 187 is sprayed. Therefore, in the first dry ice jet system, as compared with the second dry ice jet method, cracks may easily occur in the tin debris 155 due to collision of the dry ice 187 and heat shrinkage caused by the dry ice 187. When cracks easily occur in the tin debris 155, the dry ice 187 may easily enter the cracks and the tin debris 155 may be easily removed. Further, in the second dry ice jet method, the dry ice 187 is small compared with that in the first dry ice jet method. Therefore, in the second dry ice jet system, compared with the first dry ice jet method, the dry ice 187 may easily enter the minute gaps between the tin debris 155 and the surface of the reflection film 75b. When the dry ice 187 enters the gap and is vaporized and expanded in the gap, the tin debris 155 attached to the reflection film 75b may be easily removed.

Here, in the contacting step SP21, at least the tin debris 151 is exposed to tin ions and tin neutral atoms released from the plasma, and the α-tin film 153 may be deposited on at least the tin debris 151. Thus, the reflection film 75b may not be exposed to tin ions and tin neutral atoms released from the plasma, and the α-tin film 153 may not be deposited on the reflection film 75b. Further, the α-tin film 153 may be individually formed on each piece of the tin debris 151. The pressure in the environment containing hydrogen may be lower than 0.1 Pa or higher than 1000 Pa.

### 5. Description of Cleaning Method for Extreme Ultraviolet Light Reflection Mirror in Second Embodiment

Next, the cleaning method of a second embodiment will be described. Any component same as that described above is denoted by an identical reference sign, and duplicate description thereof is omitted unless specific description is needed.

### 5.1 Cleaning Method for Extreme Ultraviolet Light Reflection Mirror

FIG. 15 is a diagram showing an example of a flowchart of the cleaning method in the present embodiment. The flowchart of the present embodiment differs from the flowchart of the first embodiment in that a depositing step SP31 is included between the state at start and the contacting step SP21.

### (Depositing Step SP31)

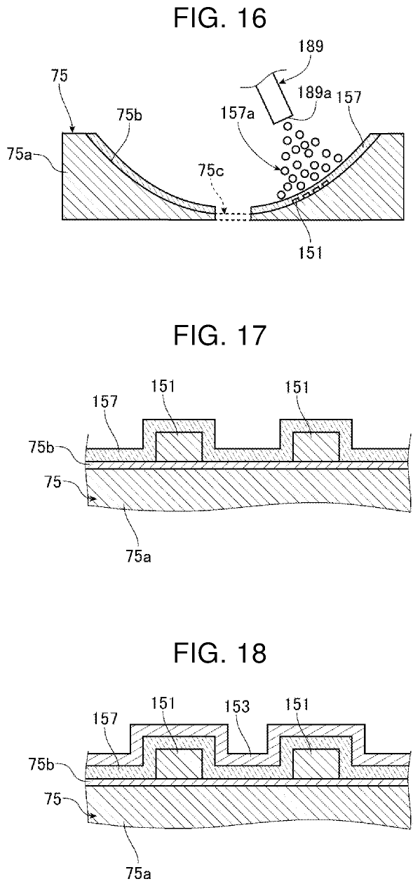

FIG. 16 is a view showing the state in the present step. FIG. 17 is an enlarged sectional view of the EUV light reflection mirror 75 around the tin debris 151 shown in FIG. 16. In FIG. 16, for ease of viewing, only one piece of tin debris 151 is denoted by a reference numeral, and the reference numerals of the other pieces of tin debris 151 are omitted. In FIG. 17, two pieces of tin debris 151 among the tin debris 151 shown in FIG. 16 are shown in an enlarged manner.

The present step is a step of depositing a β-tin film 157 containing β-tin 157a on the reflection film 75b to which the tin debris 151 is attached. FIG. 16 shows an example in which a depositing device 189 sprays liquid droplets of the β-tin 157a from a nozzle hole 189a toward the tin debris 151 scattered on the reflection film 75b and the reflection film 75b, and the β-tin film 157 is deposited on the tin debris 151 and the reflection film 75b. Although the shape of the atomized β-tin 157a is shown as a circle in FIG. 16, the shape is not particularly limited. Although the thickness of the β-tin film 157 is substantially the same at any position, the β-tin film 157 deposited on the tin debris 151 may be thicker or thinner than the β-tin film 157 deposited on the reflection film 75b. The particle diameter of the β-tin 157a is approximately equal to or larger than 15 μm and equal to or smaller than 25 μm. Therefore, even when the β-tin 157a having temperature equal to or higher than the melting point is sprayed, since the particle diameter is small, the heat capacity of the β-tin film 157 is reduced, and the thermal damage on the reflection film 75b by the β-tin film 157 having such temperature is negligible, and the temperature increase of the tin debris 151 is suppressed. The β-tin film 157 deposited on the reflection film 75b is a protective film which protects the reflection film 75b from tin ions and tin neutral atoms released from the tin plasma in the contacting step SP21. In the present step, the β-tin film 157 is deposited in an environment containing hydrogen or in a vacuum environment. The pressure in the environment containing hydrogen is approximately equal to or higher than 0.1 Pa and equal to or lower than 1000 Pa, and the pressure in the vacuum environment is approximately equal to or lower than 1×10⁻³ Pa. Note that the β-tin film 157 does not necessarily have to be deposited on the tin debris 151, and may be deposited on at least a part of the region of the reflection film 75b excluding the tin debris 151. The depositing device 189 may form the β-tin film 157 as described above by vapor deposition. The pressure in the environment containing hydrogen may be lower than 0.1 Pa or higher than 1000 Pa. The pressure in the vacuum environment may be higher than 1×10⁻³ Pa.

When the β-tin film 157 is deposited on the tin debris 151 and the reflection film 75b, the flow proceeds to the contacting step SP21.

### (Contacting Step SP21)

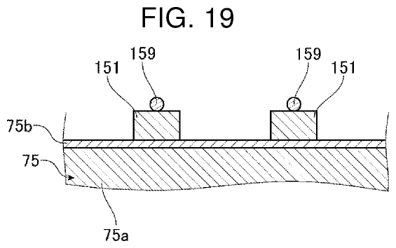

FIG. 18 is an enlarged sectional view of the EUV light reflection mirror 75 around the tin debris 151 in the present step. In the present step, α-tin is brought into contact with the β-tin film 157 so that β-tin in the β-tin film 157 is turned into tin pest, and α-tin in the tin pest is brought into contact with the tin debris 151. In the present step, as in the contacting step SP21 of the first embodiment, the α-tin film 153 is deposited on the β-tin film 157 by exposure to tin ions and tin neutral atoms released from the plasma generated in the environment containing hydrogen. In the contacting step SP21 of the first embodiment, each energy of tin ions and tin neutrals is approximately smaller than 0.5 eV so that damage and deterioration of the reflection film 75b can be suppressed. However, in the present embodiment, the protective film of the β-tin film 157 is deposited as described above. Therefore, in the contacting step SP21 of the present embodiment, each energy is approximately equal to or larger than 0.5 eV. Further, the collision flux of tin ions is approximately equal to or larger than 1×10⁷ (Sn ion/m²/5 ms) and equal to or smaller than 1×10¹⁰ (Sn ion/m²/5 ms). The exposure time of plasma is set to approximately 5 minutes, which is shorter than the exposure time in the first embodiment. As a result, seed crystals of α-tin are generated on the surface of the β-tin film 157, and the α-tin film 153 is deposited on the β-tin film 157. When the α-tin film 153 is deposited on the β-tin film 157, the β-tin film 157 is turned into tin pest, and α-tin that has undergone phase transition from β-tin of the β-tin film 157 comes into contact with the tin debris 151. As a result, the tin debris 151 is turned into tin pest. Here, the collision flux of tin ions may be smaller than 1×10⁷ (Sn ion/m²/5 ms) or larger than 1×10¹⁰ (Sn ion/m²/5 ms). The exposure time may be longer than 5 minutes.

### (Aging Step SP22 and Removing Step SP23)

In the aging step SP22, the EUV light reflection mirror 75 including the tin debris 151, the α-tin film 153, and the β-tin film 157 is stored in the storage device in the same manner as in the first embodiment. When the EUV light reflection mirror 75 is stored in the storage device, turning into tin pest of the tin debris 151 and the β-tin film 157 is promoted, and the tin debris 155 turned into tin pest is generated. Although not shown, the tin debris 155 is formed of the α-tin film 153, the β-tin film 157 which has been turned into tin pest by the α-tin film 153, and the tin debris 151 which has been turned into tin pest by α-tin undergone phase transition from β-tin of the β-tin film 157. The tin debris 155 is removed in the removing step SP23 as in the first embodiment. Therefore, in the removing step SP23, the β-tin film 157 turned into tin pest is also removed from the EUV light reflection mirror 75.

Here, a part of the aging step SP22 may overlap with the contacting step SP21, and the contacting step SP21 may be performed under the temperature environment below the freezing point in the aging step SP22. When the α-tin film 153 is deposited on the β-tin film 157 in the contacting step SP21, α-tin comes into contact with the β-tin film 157 in the aging step SP22 in which the contacting step SP21 overlaps, thereby promoting turning into tin pest of the β-tin film 157. When turning into tin pest of the β-tin film 157 is promoted, in the aging step SP22, α-tin undergone phase-transition from β-tin of the β-tin film 157 contacts with the tin debris 151, thereby promoting turning into tin pest of the tin debris 151.

### 5.2 Effects

The cleaning method of the present embodiment further includes, before the contacting step SP21, the depositing step SP31 of depositing the β-tin film 157 containing the β-tin 157a on the reflection film 75b to which the tin debris 151 is attached. In this case, the β-tin film 157 can be easily deposited as compared with a case in which the β-tin film 157 is deposited only on the tin debris 151. Further, in the contacting step SP21 of the cleaning method of the present embodiment, α-tin is brought into contact with the β-tin film 157 so that the β-tin 157a in the β-tin film 157 is turned into tin pest, and α-tin in the tin pest is brought into contact with the tin debris 151. Further, in the aging step SP22, the β-tin film 157 is left at a temperature environment below the freezing point to promote turning into tin pest of the β-tin film 157, and in the removing step SP23, the β-tin film 157 turned into tin pest is removed from the EUV light reflection mirror 75. Therefore, remaining of the β-tin film 157 on the EUV light reflection mirror 75 can be suppressed, and decrease in reflectance of the reflection film 75b due to the β-tin film 157 can be suppressed. Here, as the surface area of the β-tin film 157 increases, the area of the β-tin film 157 exposed to tin ions and tin neutral atoms may increase. As the area increases, seed crystals of α-tin may be easily generated in the β-tin film 157 in the contacting step SP21.

In the contacting step SP21 of the cleaning method of the present embodiment, the α-tin film 153 is deposited on the β-tin film 157. In this case, as compared with a case in which α-tin is brought into point contact with the β-tin film 157, the contact portion between α-tin and β-tin is widened, and turning into tin pest of the β-tin film 157 may be promoted.

Further, in the cleaning method of the present embodiment, each energy of tin ions and tin neutral atoms released from the plasma is equal to or larger than 0.5 eV. Thus, the exposure time of plasma in the contacting step SP21 may be shorter than that in a case in which the energy is smaller than 0.5 eV. Further, the reflection film 75b is protected from tin ions and tin neutral atoms by the β-tin film 157. Therefore, as compared with a case in which the β-tin film 157 is not deposited on the reflection film 75b, entering of tin ions and tin neutral atoms to the reflection film 75b can be suppressed by the β-tin film 157 even if the energy is equal to or larger than 0.5 eV in the contacting step SP21. As a result, damage to the protective film by tin ions and tin neutral atoms and deterioration of the reflective main body film due to tin ions and tin neutral atoms can be suppressed. However, the energy may be smaller than 0.5 eV.

### 6. Description of Cleaning Method for Extreme Ultraviolet Light Reflection Mirror in Third Embodiment

Next, the cleaning method of a third embodiment will be described. Any component same as that described above is denoted by an identical reference sign, and duplicate description thereof is omitted unless specific description is needed.

### 6.1 Cleaning Method for Extreme Ultraviolet Light Reflection Mirror

The flowchart of the cleaning method of the present embodiment is the same as the flowchart of the cleaning method of the first embodiment, but the contacting step SP21 of the present embodiment differs from the contacting step SP21 in the first embodiment.

### (Contacting Step SP21)

The present step is different from the contacting step SP21 in the first embodiment, in which the α-tin film 153 containing α-tin is deposited on the tin debris 151, in that tin 159 containing α-tin is brought into contact with the tin debris 151. FIG. 19 is an enlarged sectional view of the EUV light reflection mirror 75 around the tin debris 151 in the present step. Since most of the tin 159 is α-tin, the tin 159 is sand granular. FIG. 19 shows an example in which the sand granular tin 159 contacts with each of the scattered tin debris 151. The particle diameter of the tin 159 is approximately equal to or larger than 10 nm and equal to or smaller than 20 nm, but is not particularly limited.

Here, the tin 159 may be pressed against the tin debris 151. The pressure for pressing is approximately equal to or higher than 10 g/cm² and equal to or lower than 10 kg/cm², and the time of the pressing is approximately equal to or shorter than 10 seconds. The tin 159 may be pressed by a finger or the like of a worker who performs cleaning, or may be pressed by a member including a curved surface having the same curvature as the curvature of the curved surface of the EUV light reflection mirror 75. The pressure, time, and manner of pressing are not limited to the above.

### (Aging Step SP22 and Removing Step SP23)

In the aging step SP22, the EUV light reflection mirror 75 including the tin debris 151 and the tin 159 is stored in the storage device in the same manner as in the first embodiment. When the EUV light reflection mirror 75 is stored in the storage device, turning into tin pest of the tin debris 151 is promoted, and the tin debris 155 turned into tin pest is generated. Although not shown, the tin debris 155 is formed of the tin 159 and the tin debris 151 which has been turned into tin pest by the tin 159. The tin debris 155 is removed in the removing step SP23 as in the first embodiment.

### 6.2 Effects

In the contacting step SP21 of the cleaning method of the present embodiment, the tin 159 containing α-tin is attached to the tin debris 151. As a result, the tin debris 151 can be turned into tin pest without using plasma. The surface of the tin debris 151 is covered by an oxide film in some cases. In such cases, it may be difficult for the tin 159 to come into contact with the tin debris 151 due to the oxide film by only contacting with the oxide film. In such a case, when the tin 159 is pressed, the tin 159 penetrates the oxide film by the pressing and contacts with the tin debris 151. Therefore, when the tin 159 is pressed against the tin debris 151, the tin 159 can more easily contact with the tin debris 151 and turning into tin pest can be promoted as compared with a case in which the tin 159 is not pressed against the tin debris 151. The pressing may also be performed on the β-tin film 157 in the contacting step SP21 of the second embodiment. Further, in the present embodiment, a part of the aging step SP22 may overlap with the contacting step SP21, and the contacting step SP21 may be performed under the temperature environment below the freezing point in the aging step SP22.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A cleaning mg method for an extreme ultraviolet light reflection mirror, comprising:
a contacting step of bringing α-tin into contact with solid tin debris attached to an extreme ultraviolet light reflection mirror;
an aging step of leaving the tin debris brought into contact with the α-tin in a temperature environment below a freezing point to promote turning into tin pest of the tin debris; and
a removing step of removing the tin debris turned into tin pest from the extreme ultraviolet light reflection mirror.

2. The cleaning method for an extreme ultraviolet light reflection mirror according to claim 1,
wherein, in the contacting step, an α-tin film containing the α-tin is deposited on the tin debris.

3. The cleaning method for an extreme ultraviolet light reflection mirror according to claim 2,
wherein thickness of the α-tin film is equal to or larger than 20 μm and equal to or smaller than 1 mm.

4. The cleaning method for an extreme ultraviolet light reflection mirror according to claim 2,
wherein, in the contacting step, the α-tin film is deposited on the tin debris due to tin ions and tin neutral atoms released from tin plasma generated in an environment containing hydrogen.

5. The cleaning method for an extreme ultraviolet light reflection mirror according to claim 4,
wherein pressure in the environment containing hydrogen is equal to or higher than 0.1 Pa and equal to or lower than 1000 Pa.

6. The cleaning method for an extreme ultraviolet light reflection mirror according to claim 4,
wherein the α-tin film is deposited on the tin debris due to the tin ions and the tin neutral atoms released from the plasma generated by irradiating liquid droplet tin or solid tin with laser light.

7. The cleaning method for an extreme ultraviolet light reflection mirror according to claim 4,
wherein each energy of the tin ions and the tin neutral atoms is smaller than 0.5 eV.

8. The cleaning method for an extreme ultraviolet light reflection mirror according to claim 2,
wherein the α-tin film is deposited by sputtering.

9. The cleaning method for an extreme ultraviolet light reflection mirror according to claim 1,
wherein, in the aging step, temperature of the temperature environment is equal to or higher than −50° C. and equal to or lower than −20° C.

10. The cleaning method for an extreme ultraviolet light reflection mirror according to claim 1,
wherein proportion of moisture in an environment in which each of the aging step and the removing step is performed is equal to or lower than 0.1 wt %.

11. The cleaning method for an extreme ultraviolet light reflection mirror according to claim 1,
wherein, in the removing step, the tin debris turned into tin pest is removed by a jet.

12. The cleaning method for an extreme ultraviolet light reflection mirror according to claim 11,
wherein, in the removing step, pellet-like dry ice is sprayed toward the tin debris turned into tin pest.

13. The cleaning method for an extreme ultraviolet light reflection mirror according to claim 11,
wherein, in the removing step, snow-like dry ice is sprayed toward the tin debris turned into tin pest.

14. The cleaning method for an extreme ultraviolet light reflection mirror according to claim 1,
further comprising, before the contacting step, a depositing step of depositing a β-tin film containing β-tin on the extreme ultraviolet light reflection mirror to which the tin debris is attached,
wherein, in the contacting step, the β-tin in the β-tin film is turned into tin pest by bringing α-tin into contact with the β-tin film and the α-tin in tin pest is brought into contact with the tin debris, and
in the aging step, the β-tin film is left at the temperature environment to promote turning into tin pest of the β-tin film, and in the removing step, the β-tin film turned into tin pest is removed from the extreme ultraviolet light reflection mirror.

15. The cleaning method for an extreme ultraviolet light reflection mirror according to claim 14,
wherein, in the contacting step, an α-tin film containing the α-tin is deposited on the β-tin film.

16. The cleaning method for an extreme ultraviolet light reflection mirror according to claim 15,
wherein, in the contacting step, the α-tin film is deposited on the β-tin film due to tin ions and tin neutral atoms released from tin plasma generated in an environment containing hydrogen.

17. The cleaning method for an extreme ultraviolet light reflection mirror according to claim 16,
wherein each energy of the tin ions and the tin neutral atoms is equal to or larger than 0.5 eV.

18. The cleaning method for an extreme ultraviolet light reflection mirror according to claim 1,
wherein, in the contacting step, the α-tin is pressed against the tin debris.
